(19) United States
(12) Patent Application Publication
(10) Pub. No.: US 2026/0144036 A1
(43) Pub. Date: May 21, 2026

(54) SEMICONDUCTOR PACKAGE

(71) Applicant: SAMSUNG ELECTRONICS CO., LTD., Suwon-si (KR)

(72) Inventors: Jongho PARK, Suwon-si (KR); Jaemok JUNG, Suwon-si (KR); Tae Oh HA, Suwon-si (KR); Chanwook PARK, Suwon-si (KR)

(73) Assignee: SAMSUNG ELECTRONICS CO., LTD., Suwon-si (KR)

(21) Appl. No.: 19/254,980

(22) Filed: Jun. 30, 2025

(30) Foreign Application Priority Data
Nov. 15, 2024 (KR) 10-2024-0163493

(51) Int. Cl. H01L 23/00; H01L 23/31; H01L 23/48; H01L 25/04

(52) U.S. Cl. CPC H10W 20/20; H10W 74/131; H10W 90/00; H10W 72/934; H10W 74/15; H10W 90/722; H10W 90/732

(57) ABSTRACT

A semiconductor package may include a first semiconductor chip and a second semiconductor chip disposed on the first semiconductor chip in a stacking direction. The first semiconductor chip may include a semiconductor substrate, a penetration via penetrating the semiconductor substrate, a protection insulating structure disposed on a top surface of the semiconductor substrate, and an upper pad disposed on the penetration via. The upper pad may include a center region, which overlaps the penetration via in the stacking direction, and an edge region enclosing the center region. The second semiconductor chip may include a connection terminal in contact with the upper pad. The penetration via and the protection insulating structure may have top surfaces located at different levels. The center and edge regions of the upper pad may have top surfaces located at different levels.

### CROSS-REFERENCE TO RELATED APPLICATIONS

This U.S. non-provisional patent application claims priority under 35 U.S.C. § 119 to Korean Patent Application No. 10-2024-0163493, filed on Nov. 15, 2024, in the Korean Intellectual Property Office, the entire contents of which are hereby incorporated by reference.

### BACKGROUND OF THE INVENTION

The present disclosure relates to a semiconductor package.

Due to the rapid development of the electronic industry and the increase in the diversity of user needs, electronic devices are required to have reduced sizes and more functions. Accordingly, semiconductor devices used in the electronic devices are also required to be smaller and offer more functionality. Thus, a semiconductor package, in which a plurality of semiconductor chips having penetration vias are stacked through adhesive layers therebetween in a vertical direction, has been proposed.

### SUMMARY

An embodiment of the inventive concept provides a semiconductor package with improved reliability.

An embodiment of the inventive concept provides a semiconductor package, which is efficiently fabricated by simplifying a process of forming a pad of a semiconductor chip.

According to an embodiment of the inventive concept, a semiconductor package may include a first semiconductor chip and a second semiconductor chip disposed on the first semiconductor chip in a stacking direction. The first semiconductor chip may include a first semiconductor substrate, a first penetration via penetrating the first semiconductor substrate, a protection insulating structure disposed on a top surface of the first semiconductor substrate, and a first upper pad disposed on the first penetration via. The first upper pad may include a center region, which overlaps the first penetration via in the stacking direction, and an edge region enclosing the center region. The second semiconductor chip may include a connection terminal in contact with the first upper pad. A top surface of first the penetration via may be located at a first level, and a top surface of the protection insulating structure may be located at a second level. A top surface of the center region of the first upper pad may be located at a third level, and a top surface of the edge region of the first upper pad may be located at a fourth level. The first and second levels may be different from each other, and the third and fourth levels may be different from each other.

According to an embodiment of the inventive concept, a semiconductor package may include a first semiconductor chip and a second semiconductor chip disposed on the first semiconductor chip in a stacking direction. The first semiconductor chip may include a semiconductor substrate, a penetration via penetrating the semiconductor substrate, a protection insulating structure disposed on the semiconductor substrate, and an upper pad disposed on the penetration via. A top surface of the penetration via may be located at a level different from a top surface of the protection insulating structure. The second semiconductor chip may include a lower pad disposed on the upper pad and a connection terminal between the upper pad and the lower pad. The upper pad may include a center region overlapping the penetration via in the stacking direction, and the center region may have a top surface with an uneven structure.

According to an embodiment of the inventive concept, a semiconductor package may include a package substrate, an interposer disposed on the package substrate, a sub-semiconductor package disposed on the interposer, and a first semiconductor chip horizontally spaced apart from the sub-semiconductor package. The sub-semiconductor package may include a second semiconductor chip and a third semiconductor chip stacked on the second semiconductor chip in a vertical direction. Each of the second and third semiconductor chips may include a semiconductor substrate including a first surface and a second surface facing each other, a protection insulating structure disposed on the first surface of the semiconductor substrate, an interconnection layer disposed on the second surface of the semiconductor substrate, an upper pad disposed on the protection insulating structure, a penetration via connected to the interconnection layer and the upper pad and penetrating the semiconductor substrate, a lower pad disposed on the interconnection layer, and a connection terminal disposed on the lower pad. The connection terminal may be interposed between the upper pad of the second semiconductor chip and the lower pad of the third semiconductor chip. A top surface of the penetration via of the second semiconductor chip may be located at a first level, and the first surface of the semiconductor substrate of the second semiconductor chip may be located at a second level. The first level may be lower than the second level, and a bottom surface of the lower pad of the third semiconductor chip may be flatter than a top surface of the upper pad of the second semiconductor chip.

### BRIEF DESCRIPTION OF THE DRAWINGS

FIG. 1 is a sectional view illustrating a semiconductor package according to an embodiment of the inventive concept.

FIG. 2 is an enlarged sectional view illustrating a portion EV1 of FIG. 1.

FIG. 3 is a sectional view illustrating a semiconductor package according to an embodiment of the inventive concept.

FIG. 4 is an enlarged sectional view illustrating a portion EV2 of FIG. 3.

FIG. 5 is a sectional view illustrating a semiconductor package according to an embodiment of the inventive concept.

FIGS. 6A, 6B, 6C, 6D, 6E, 6F, 6G, 6H, 6I, 6J, and 6K are sectional views illustrating a process of fabricating a semiconductor package, according to an embodiment of the inventive concept.

FIGS. 7A, 7B, 7C, and 7D are sectional views illustrating a process of fabricating a semiconductor package, according to an embodiment of the inventive concept.

FIG. 8 is a sectional view illustrating a semiconductor package according to an embodiment of the inventive concept.

FIG. 9 is an enlarged sectional view illustrating a portion EV3 of FIG. 8.

FIG. 10 is a sectional view illustrating a semiconductor package according to an embodiment of the inventive concept.

FIG. 11 is an enlarged sectional view illustrating a portion EV4 of FIG. 10.

FIGS. 12A, 12B, and 12C are sectional views illustrating a process of fabricating a semiconductor package, according to an embodiment of the inventive concept.

FIGS. 13A, 13B, 13C, and 13D are sectional views illustrating a process of fabricating a semiconductor package according to an embodiment of the inventive concept.

### DETAILED DESCRIPTION

Example embodiments of the inventive concepts will now be described more fully with reference to the accompanying drawings, in which example embodiments are shown.

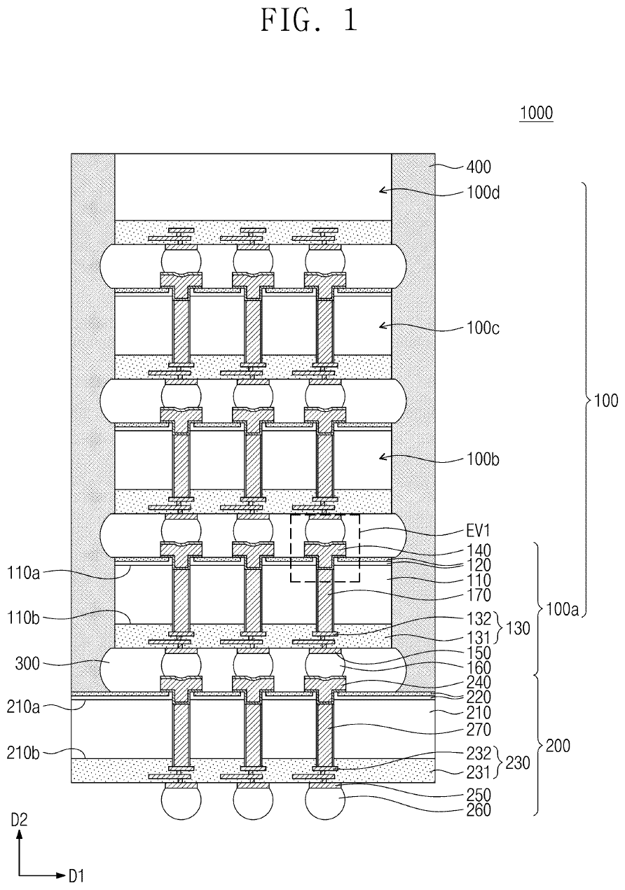

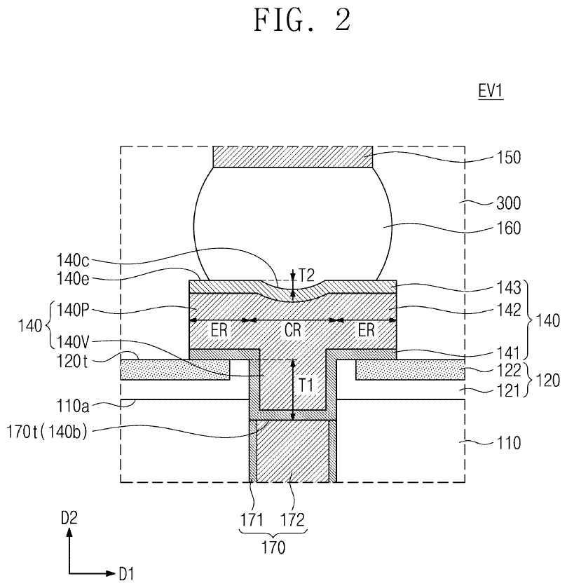

FIG. 1 is a sectional view illustrating a semiconductor package 1000 according to an embodiment of the inventive concept. FIG. 2 is an enlarged sectional view illustrating a portion EV1 of FIG. 1. In the present specification, a first direction D1 may be a horizontal direction, and a second direction D2 may be a vertical direction (or a stacking direction). The first direction D1 may be substantially parallel to a top surface of a semiconductor substrate 110 or 210, which will be described below. The second direction D2 may be substantially perpendicular to the top surface of the semiconductor substrate 110 or 210. One or ordinary skill in the art would understand that the expression “substantially parallel” may mean not only being exactly parallel (0°) but also being close to parallel including process errors, positional deviations, and/or measurement errors that may occur in a manufacturing process, and the range thereof may be widely accepted in the art. Likewise, one or ordinary skill in the art would understand that the expression “substantially perpendicular” may mean not only being exactly perpendicular (90°) but also being close to perpendicular including process errors, positional deviations, and/or measurement errors that may occur in a manufacturing process, and the range thereof may be widely accepted in the art.

Referring to FIGS. 1 and 2, a semiconductor package 1000 may include a chip stack 100, a base chip 200, an adhesive layer 300, and a mold layer 400. The chip stack 100 may include a plurality of semiconductor chips (e.g., a first semiconductor chip 100a, a second semiconductor chip 100b, a third semiconductor chip 100c, and a fourth semiconductor chip 100d), which are stacked in the second direction D2. The chip stack 100 is illustrated to have four semiconductor chips, and the number of the semiconductor chips is not limited to four. For example, the chip stack 100 may be configured to include 4 to 32 semiconductor chips. All of the first to fourth semiconductor chips 100a, 100b, 100c, and 100d may be configured to have the same memory integrated circuit. Such a memory integrated circuit may be a volatile memory integrated circuit (e.g., DRAM or SRAM integrated circuit) or a nonvolatile memory integrated circuit (e.g., PRAM, MRAM, FeRAM, or RRAM integrated circuit). For example, the first to fourth semiconductor chips 100a to 100d may be a DRAM chip including the DRAM integrated circuit, but not limited thereto.

The first semiconductor chip 100a may include a first semiconductor substrate 110, first penetration vias 170, first upper pads 140, first lower pads 150, first connection terminals 160, a first interconnection layer 130, and a first protection insulating structure 120. The second semiconductor chip 100b and the third semiconductor chip 100c may have substantially the same structure as the first semiconductor chip 100a. The fourth semiconductor chip 100d may be the uppermost one of the semiconductor chips in the chip stack 100. The fourth semiconductor chip 100d may not include the first penetration vias 170, the first upper pads 140, and the first protection insulating structure 120. The first semiconductor substrate 110 of the fourth semiconductor chip 100d may be thicker than the first semiconductor substrate 110 of the first semiconductor chip 100a. Except for these, the fourth semiconductor chip 100d may have substantially the same structure as the first semiconductor chip 100a.

The first semiconductor substrate 110 may contain a semiconductor element (e.g., silicon (Si) or germanium (Ge)). In an embodiment, the first semiconductor substrate 110 may have a silicon-on-insulator (SOI) structure. The first semiconductor substrate 110 may include a conductive region (e.g., a well region doped with impurities or an impurity-doped structure). The first semiconductor substrate 110 may include various device isolation structures (e.g., a shallow trench isolation (STI) structure). The first semiconductor substrate 110 may include a first surface 110a and a second surface 110b, which are opposite to each other. The first surface 110a of the first semiconductor substrate 110 may be referred to as a top surface, and the second surface 110b may be referred to as a bottom surface. Memory integrated circuits may be disposed on the second surface 110b. The first surface 110a may be referred to as a rear surface, and the second surface 110b may be referred to as a front surface.

The first interconnection layer 130 may be disposed on the second surface 110b of the first semiconductor substrate 110. The first interconnection layer 130 may include a first insulating layer 131 and a first interconnection structure 132 disposed in the first insulating layer 131. The first interconnection structure 132 may include, for example, interconnection lines and/or contacts. The memory integrated circuit may be electrically connected to the first connection terminal 160 through the first interconnection structure 132. The first interconnection structure 132 may be formed of or include at least one of metallic materials (e.g., copper and aluminum). The first insulating layer 131 may be formed of or include at least one of silicon oxide or silicon nitride.

The first lower pads 150 may be disposed on the first interconnection layer 130. The first lower pads 150 may be formed of or include at least one of metallic materials (e.g., copper, nickel, and aluminum). The first connection terminals 160 may be disposed on the first lower pad 150. The first connection terminal 160 may be formed of or include at least one of tin (Sn), silver (Ag), copper (Cu), nickel (Ni), bismuth (Bi), indium (In), antimony (Sb), cerium (Ce), or alloys thereof.

The first protection insulating structure 120 may be disposed on the first surface 110a of the first semiconductor substrate 110. As shown in FIG. 2, the first protection insulating structure 120 may include a first protection layer 121 and a second protection layer 122. The first protection layer 121 may be in contact with the first surface 110a of the first semiconductor substrate 110 and may be in contact with a side surface of a via portion 140V and a bottom surface of a pad portion 140P of a first upper pad 140, which will be described below. A bottom surface of the second protection layer 122 may be in contact with a top surface of the first protection layer 121. A top surface of the second protection layer 122 may be in contact with a bottom surface of the pad portion 140P of the first upper pad 140. The first protection layer 121 and the second protection layer 122 may include different insulating materials from each other. The second protection layer 122 may include a material having an etch selectivity with respect to the first protection layer 121. For example, the first protection layer 121 may be a silicon oxide layer, and the second protection layer 122 may be a silicon nitride layer.

The first penetration via 170 may penetrate the first semiconductor substrate 110. The first penetration via 170 may have a pillar shape. As shown in FIG. 2, the first penetration via 170 may include a barrier layer 171 serving as an outer surface and a conductive filling layer 172 serving as an inner portion. The barrier layer 171 may be formed of or include at least one of Ti, TiN, Ta, TaN, Ru, Co, Mn, WN, Ni, or NiB. The conductive filling layer 172 may be formed of or include at least one of Cu alloys (e.g., Cu, CuSn, CuMg, CuNi, CuZn, CuPd, CuAu, CuRe, and CuW). A via insulating layer may be interposed between the first penetration via 170 and the first semiconductor substrate 110 or between the first penetration via 170 and the first interconnection layer 130. The via insulating layer may be formed of or include at least one of silicon oxide or silicon nitride.

A top surface 170t of the first penetration via 170 may be located at a first level, and a top surface 120t of the first protection insulating structure 120 may be located at a second level. The first level may be different from the second level. The first level may be lower than the second level. A difference between the first and second levels (i.e., T1) may be equal to or larger than 0.2 μm. For example, the difference between the first and second levels (T1) may range from 0.2 μm to 0.4 μm. The top surface 170t of the first penetration via 170 may be located at a level lower than the top surface 110a of the first semiconductor substrate 110.

A plurality of upper pads 140, which are connected to the first penetration vias 170, may be disposed on the first protection insulating structure 120. Each of the upper pads 140 may include a seed pattern 141, a first metal pattern 142, and a second metal pattern 143. The first metal pattern 142 may be disposed on the seed pattern 141. The second metal pattern 143 may be disposed on the first metal pattern 142.

The seed pattern 141 may be in contact with a top surface of the first penetration via 170, a top surface of the first protection layer 121, a top surface of the second protection layer 122, and an inner side surface of the first semiconductor substrate 110. A thickness of the seed pattern 141 may range from 5 nm to 50 nm. The seed pattern 141 may include, for example, titanium/copper. A bottom surface of the first metal pattern 142 may be in contact with a top surface of the seed pattern 141. The first metal pattern 142 may be formed of or include, for example, nickel. The first metal pattern 142 may occupy the largest proportion (in terms of weight or volume) within the first upper pad 140, compared to the seed pattern 141 and the second metal pattern 143. The second metal pattern 143 may be formed of or include, for example, gold. A thickness of the second metal pattern 143 may be smaller than a thickness of the first metal pattern 142.

The first upper pad 140 may include the via portion 140V and the pad portion 140P. The first upper pad 140 may have a “T” shape, when viewed in a sectional view. The via portion 140V may penetrate the first protection insulating structure 120 and may be extended into an upper portion of the first semiconductor substrate 110. The via portion 140V may be a portion of the first upper pad 140, which is placed between a level of the top surface 120t of the second protection layer 122 and a level of the top surface 170t of the first penetration via 170. The pad portion 140P may mean a portion of the first upper pad 140, which is placed at a higher level than the top surface 120t of the second protection layer 122. A width of the pad portion 140P in the first direction D1 may be larger than a width of the via portion 140V in the first direction D1. Each of the via and pad portions 140V and 140P may be shaped like a circular pillar. The via and pad portions 140V and 140P may have a circular shape, when viewed in a plan view. A thickness of the via portion 140V may be larger than a thickness of the first protection insulating structure 120.

The first upper pad 140 may include a center region CR and an edge region ER enclosing the same. The center region CR may include a top surface with an uneven structure. A top surface 140c of the center region CR of the first upper pad 140 may be located at a third level, and a top surface 140e of the edge region ER of the first upper pad 140 may be located at a fourth level. The third level may be lower than the fourth level. A top surface of the first upper pad 140 may have a dimple-shaped region in the center region CR. The dimple-shaped region may be a region of a concavely recessed shape. A depth T2 of the dimple-shaped region may be a difference between the third and fourth levels. In other words, the dimple-shaped region may have an increasing depth as a distance to the center of the center region CR decreases, and it may have the depth T2 at the center of the center region CR. The depth T2 of the dimple-shaped region may be less than 0.1 μm and greater than 0. The difference between the third and fourth levels (i.e., T2) may be smaller than the difference between the first and second levels (T1). The first connection terminal 160 of the second semiconductor chip 100b may be disposed on the pad portion 140P. The first connection terminal 160 may be in contact with the top surface 140c of the center region CR of the first upper pad 140 and the top surface 140e of the edge region ER.

A level of a bottom surface of the center region CR of the first upper pad 140 may be different from a level of a bottom surface of the edge region ER of the first upper pad 140. The level of the bottom surface of the center region CR of the first upper pad 140 may be lower than the level of the bottom surface of the edge region ER of the first upper pad 140. A thickness of the center region CR of the first upper pad 140 may be different from a thickness of the edge region of the first upper pad 140. The thickness of the center region CR of the first upper pad 140 may be larger than the thickness of the edge region of the first upper pad 140. A contact area between the top surface of the first upper pad 140 of the first semiconductor chip 100a and the first connection terminal 160 may be larger than a contact area between a bottom surface of the first lower pad 150 of the second semiconductor chip 100b and the first connection terminal 160. The top surface of the first upper pad 140 of the first semiconductor chip 100a may have a curved portion, compared to the bottom surface of the first lower pad 150. That is, the bottom surface of the first lower pad 150 may be flatter than the top surface of the first upper pad 140 of the first semiconductor chip 100a.

The base chip 200 may be disposed in a lower portion of the semiconductor package 1000. The base chip 200 may have a larger size than the semiconductor chips 100a, 100b, 100c, and 100d of the chip stack 100 disposed thereon. The base chip 200 may have a structure similar to the first semiconductor chip 100a. The base chip 200 may be a buffer chip. The base chip 200 may include a second semiconductor substrate 210, second penetration vias 270, a plurality of second upper pads 240, a plurality of second lower pads 250, second connection terminals 260, a second interconnection layer 230, and a second protection insulating structure 220. Here, the second semiconductor substrate 210 may include a first surface 210a and a second surface 210b, which are opposite to each other. In an embodiment, logic circuits (e.g., an interface circuit) may be disposed on the second surface 210b of the second semiconductor substrate 210. The base chip 200 may be disposed below the chip stack 100 and may be configured to transmit signals from the semiconductor chips 100a to 100d to the outside and to transmit signals and an electric power from the outside to the semiconductor chips 100a to 100d.

That is, the semiconductor package 1000 in the present embodiment may be a high bandwidth memory (HBM) package. The second penetration via 270, the second upper pad 240, the second lower pad 250, the second connection terminal 260, and the second protection insulating structure 220 may correspond, respectively, to the first penetration via 170, the first upper pad 140, the first lower pad 150, the first connection terminal 160, and the first protection insulating structure 120 described above.

The adhesive layer 300 may be interposed between the base chip 200 and the first semiconductor chip 100a and between two adjacent ones of the semiconductor chips 100a to 100d to enclose a side surface of the first connection terminal 160. The adhesive layer 300 may protrude from side surfaces of the semiconductor chips 100a to 100d in an outward direction, as shown in FIG. 1. In an embodiment, the adhesive layer 300 may be formed of a non-conductive film (NCF). In a process of stacking semiconductor chips, the NCF may be used as an adhesive layer when the semiconductor chips are bonded to each other by a thermal compression bonding (TCB) method. The adhesive layer 300 may be in contact with the second protection layer 122 and may be spaced apart from the first protection layer 121.

The mold layer 400 may be disposed to enclose a top surface of the base chip 200, a side surface of the chip stack 100, and a side surface of the adhesive layer 300. The mold layer 400 may not cover a top surface of the fourth semiconductor chip 100d. In an embodiment, the mold layer 400 may cover the top surface of the fourth semiconductor chip 100d. In an embodiment, the mold layer 400 may include an epoxy molding compound (EMC).

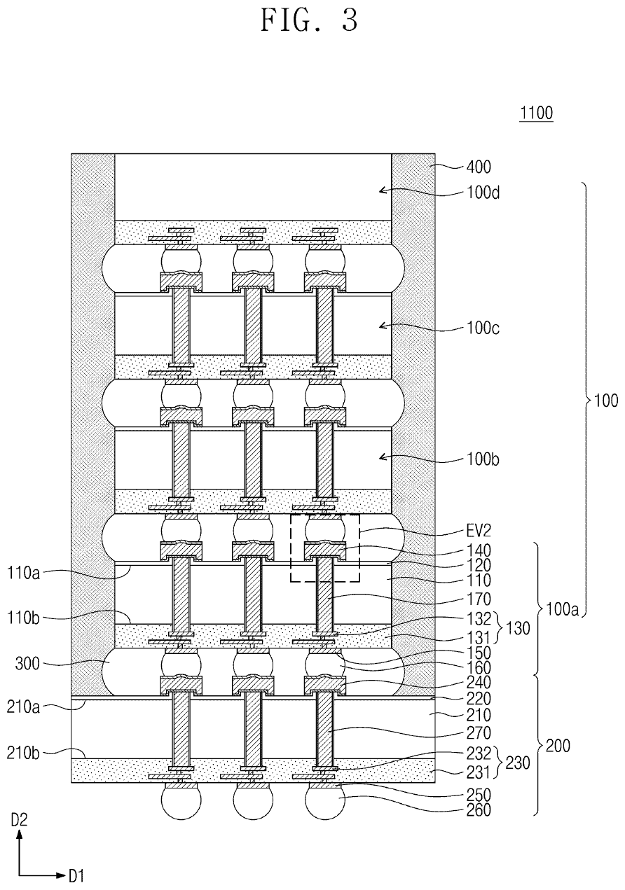

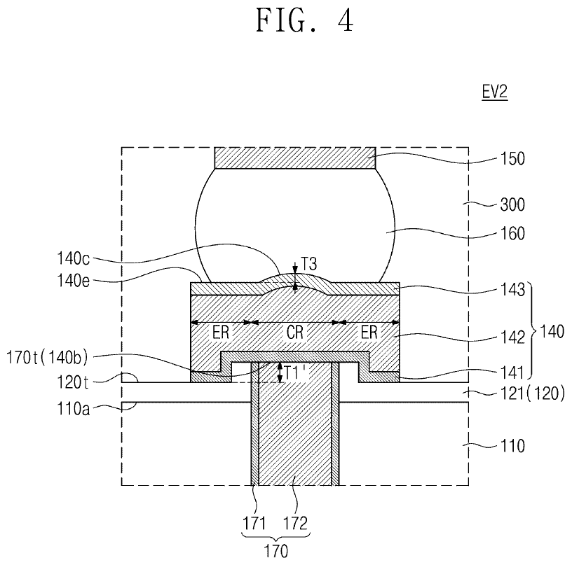

FIG. 3 is a sectional view illustrating a semiconductor package 1100 according to an embodiment of the inventive concept. FIG. 4 is an enlarged sectional view illustrating a portion EV2 of FIG. 3. Except for features to be described below, the semiconductor package 1100 according to the present embodiment may have substantially the same features as those described with reference to FIGS. 1 and 2, and thus, an overlapping description thereof may be omitted.

Referring to FIGS. 3 and 4, the first protection insulating structure 120 may not include the second protection layer 122. As a result, the top surface of the first protection layer 121 may be in contact with the seed pattern 141 and the adhesive layer 300. A side surface of the first protection layer 121 may be adjacent to a side surface of the first penetration via 170. FIGS. 3 and 4 illustrate an example, in which the side surface of the first protection layer 121 is in contact with the barrier layer 171, but in an embodiment, a via insulating layer may be interposed between the side surface of the first protection layer 121 and the barrier layer 171. The adhesive layer 300 may be in contact with the first protection layer 121.

The top surface 170t of the first penetration via 170 may be placed at the first level, the top surface 120t of the first protection insulating structure 120 may be placed at the second level different from the first level. The top surface 170t of the first penetration via 170 may be in contact with a bottom surface 140b of the first upper pad 140. The first level may be higher than the second level. The difference between the first and second levels (i.e., T1′) may be larger than 0.2 μm. For example, the difference between the first and second levels T1′ may range from 0.2 μm to 0.4 μm. The first penetration via 170 may protrude from the top surface 110a of the first semiconductor substrate 110. That is, the top surface 170t of the first penetration via 170 may be located at a level higher than the top surface 110a of the first semiconductor substrate 110.

The first upper pad 140 may have an arch shape, when viewed in a sectional view. The first upper pad 140 may have the center region CR and the edge region ER enclosing the center region CR. A top surface of the center region CR may have a dome-shaped region. Here, the dome-shaped region may be a region of a convexly protruding shape. The top surface 140c of the center region CR may be placed at the third level, and the third level may be different from the fourth level of the top surface 140e of the edge region ER. The third level may be higher than the fourth level. The dome-shaped region may have an increasing height as a distance to at the center of the center region CR decreases, and it may have a height T3 at the center of the center region CR, which is equal to the difference between the third and fourth levels. In an embodiment, the height T3 of the dome may be less than 0.1 μm and greater than 0. The difference between the third and fourth levels (i.e., T3) may be smaller than the difference between the first and second levels (T1′). A level of the bottom surface of the center region CR of the first upper pad 140 may be higher than a level of the bottom surface of the edge region ER of the first upper pad 140. A thickness of the center region CR of the first upper pad 140 may be smaller than a thickness of the edge region ER of the first upper pad 140.

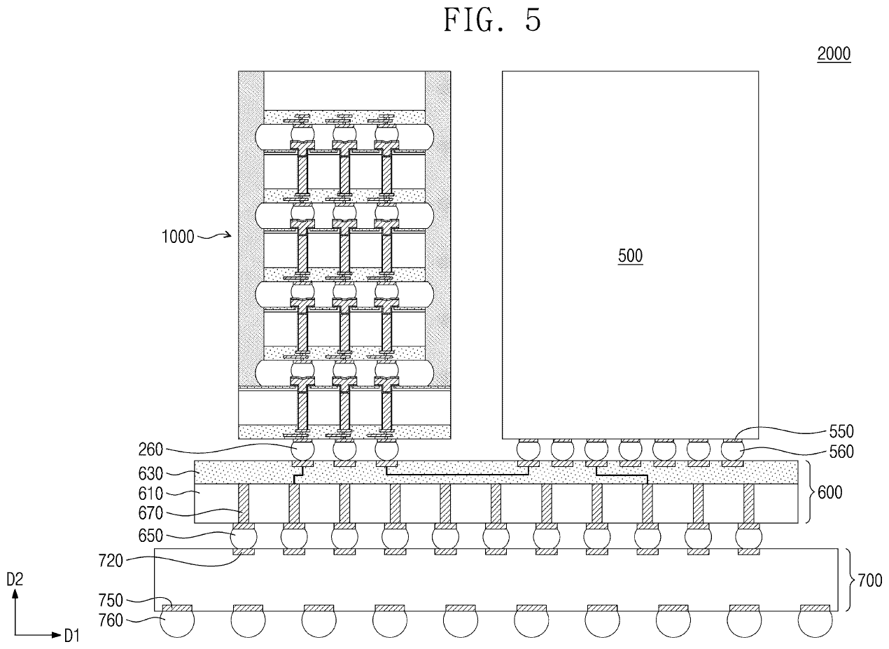

FIG. 5 is a sectional view illustrating a semiconductor package 2000 according to an embodiment of the inventive concept.

Referring to FIG. 5, the semiconductor package 1000 of FIG. 1 may be referred to as a sub-semiconductor package 1000. A semiconductor package 2000 may include the sub-semiconductor package 1000, a fifth semiconductor chip 500, an interposer 600, and a package substrate 700.

The package substrate 700 may be, for example, a printed circuit board (PCB). The package substrate 700 may include lower metal pads 750, upper metal pads 720, metal lines, and outer connection terminals 760. The upper metal pads 720 may be disposed in an upper portion of the package substrate 700, and the lower metal pads 750 may be disposed in a lower portion of the package substrate 700. The metal lines may electrically connect the upper metal pads 720 to the lower metal pads 750. The outer connection terminals 760 may be disposed on the lower metal pads 750, respectively. The outer connection terminals 760 may include a conductive material (e.g., a solder material).

The interposer 600 may be disposed on the package substrate 700. The interposer 600 may be, for example, a silicon interposer. Alternatively, the interposer 600 may be a redistribution interposer. The interposer 600 may include a third semiconductor substrate 610, third penetration vias 670, an interconnection layer 630, and inner connection terminals 650. The third semiconductor substrate 610 may include a semiconductor material (e.g., silicon or germanium), and in an embodiment, it may be a silicon substrate. The interconnection layer 630 may be disposed on the third semiconductor substrate 610. The interconnection layer 630 may include an insulating layer and an interconnection structure in the insulating layer. The interconnection structure may electrically connect the sub-semiconductor package 1000 to the third penetration via 670 and may electrically connect the fifth semiconductor chip 500 to the third penetration via 670. The interconnection structure may electrically connect the sub-semiconductor package 1000 to the fifth semiconductor chip 500. Each of the third penetration vias 670 may penetrate the third semiconductor substrate 610 and may be connected to the inner connection terminal 650 through a pad.

The fifth semiconductor chip 500 and the sub-semiconductor package 1000 may be disposed on the interposer 600. The fifth semiconductor chip 500 and the sub-semiconductor package 1000 may be spaced apart from each other in the first direction D1.

The fifth semiconductor chip 500 may be a logic chip. In an embodiment, the fifth semiconductor chip 500 may be one of a central processing unit (CPU), a graphics processing unit (GPU), and an application specific integrated circuit (ASIC). The fifth semiconductor chip 500 may be configured to transmit and receive signals to and from the sub-semiconductor package 1000. The fifth semiconductor chip 500 may include chip pads 550 disposed in a lower portion thereof. Third connection terminals 560 may be disposed on the chip pads 550, respectively. The third connection terminals 560 may include a conductive material (e.g., a solder material).

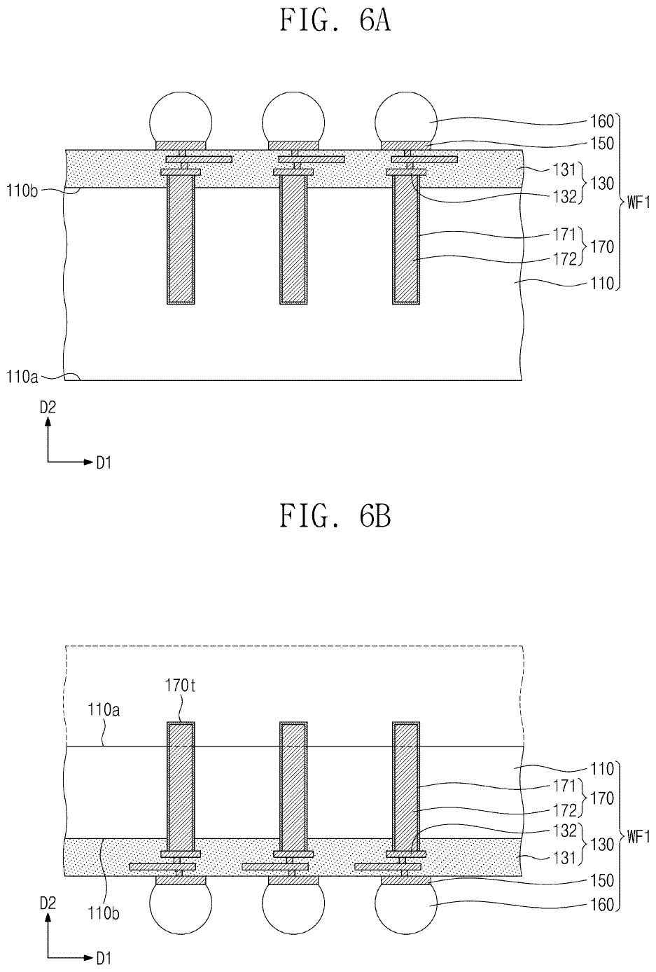

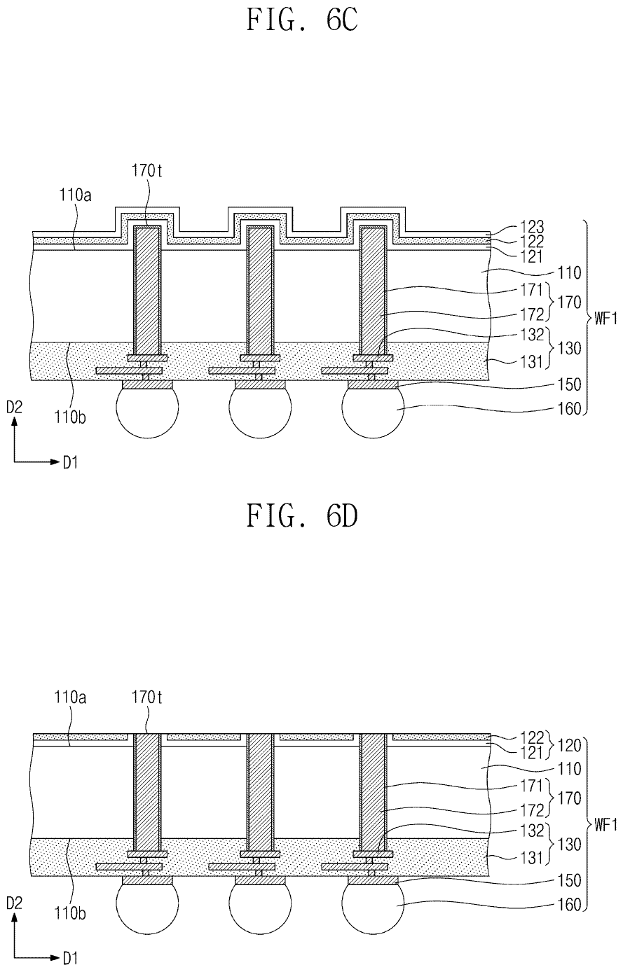

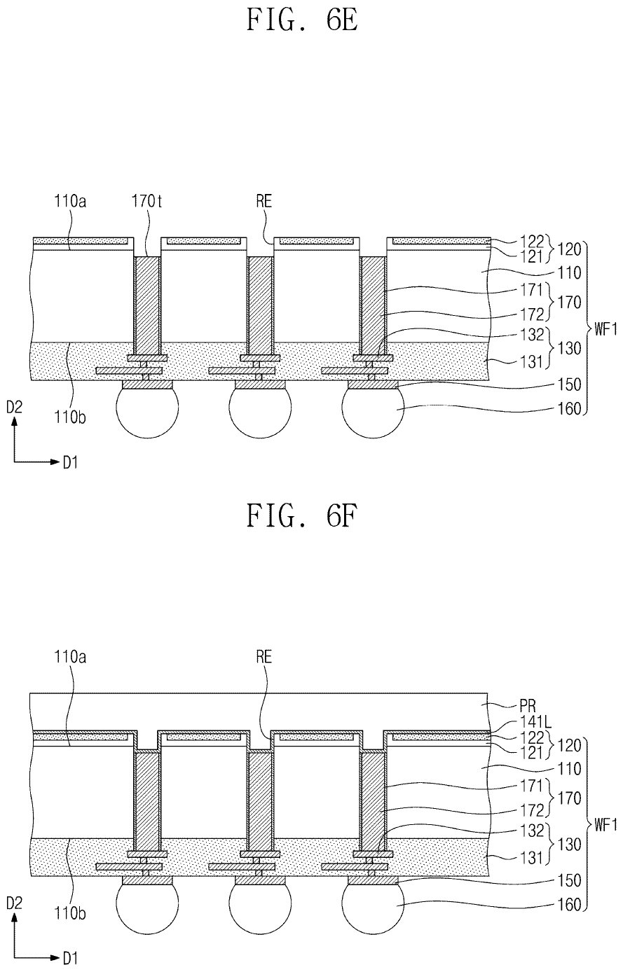

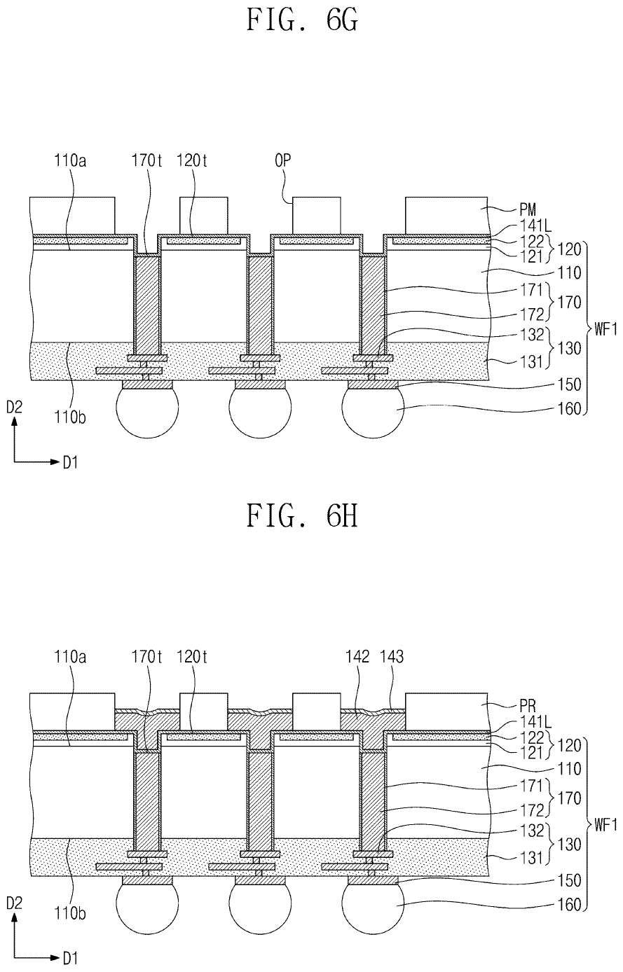

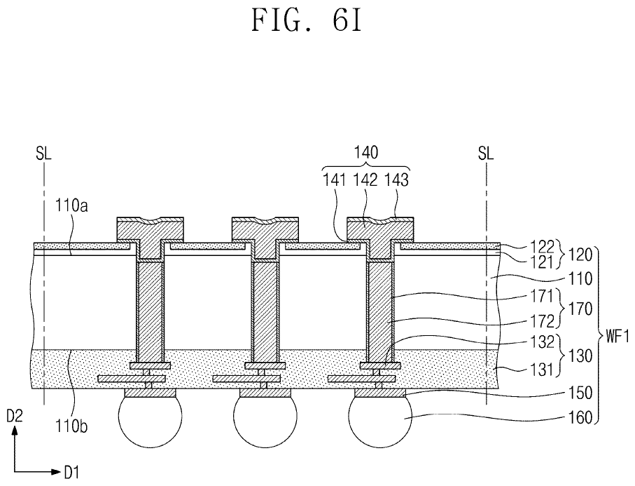

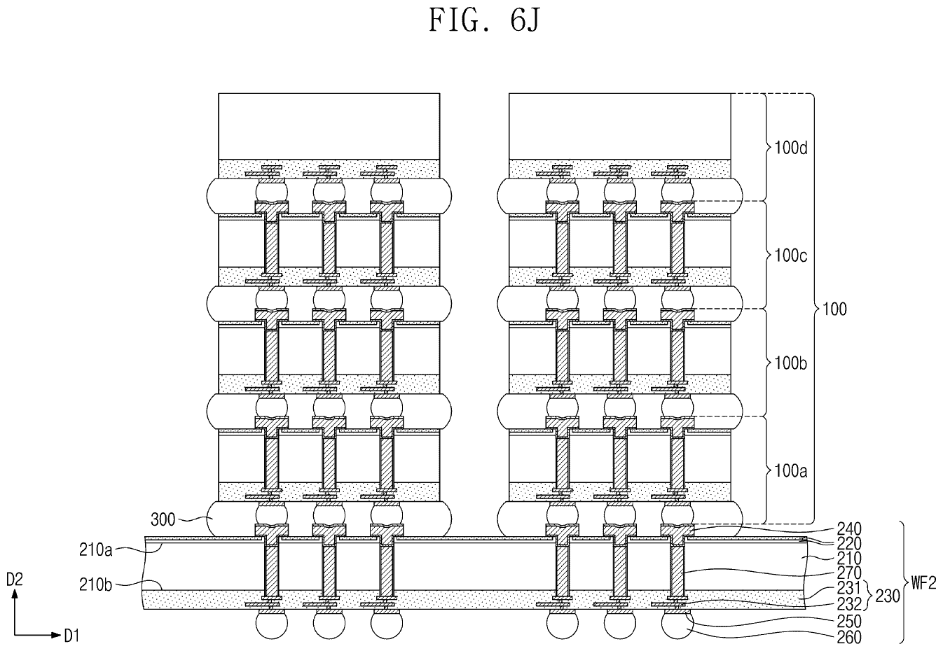

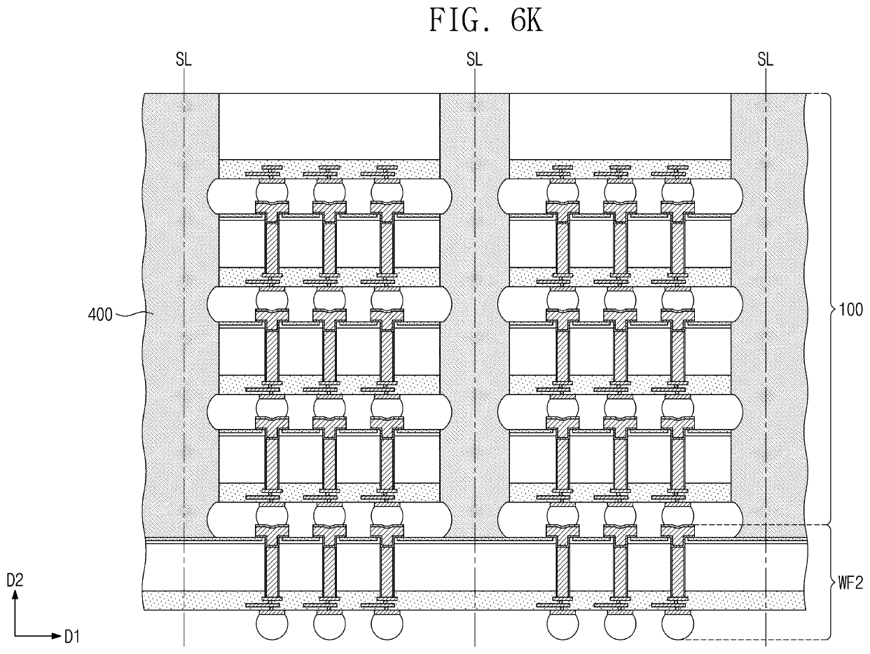

FIGS. 6A, 6B, 6C, 6D, 6E, 6F, 6G, 6H, 6I, 6J, and 6K are sectional views illustrating a process of fabricating a semiconductor package, according to an embodiment of the inventive concept. The element described with reference to FIGS. 1 and 2 may be identified by the same reference number without repeating an overlapping description thereof.

Referring to FIG. 6A, a first wafer WF1 may be provided. The first wafer WF1 may include the first semiconductor substrate 110, the first penetration vias 170, the first interconnection layer 130, the first lower pads 150, and the first connection terminals 160. The first wafer WF1 may be prepared through the following process. The first semiconductor substrate 110 may be prepared, and here, the first semiconductor substrate 110 may include the first surface 110a and the second surface 110b, which are opposite to each other. A memory integrated circuit may be formed on the second surface 110b of the first semiconductor substrate 110. Next, the first penetration vias 170 may be formed to penetrate a portion of the first semiconductor substrate 110. The formation of the first penetration vias 170 may include forming a penetration hole to penetrate a portion of the first semiconductor substrate 110 and forming a via insulating layer, the barrier layer 171, and the conductive filling layer 172 in the penetration hole. The first interconnection layer 130 may be formed on the second surface 110b of the first semiconductor substrate 110 and the first penetration vias 170. The first lower pads 150 and the first connection terminals 160 may be sequentially formed on the first interconnection layer 130.

Referring to FIG. 6B, the first wafer WF1 may be rotated by 180°. The first wafer WF1 may be disposed on a carrier substrate. A portion of the first semiconductor substrate 110 may be removed to expose end portions of the first penetration vias 170. The top surface 170t of the first penetration via 170 may be located at a level higher than the first surface 110a of the first semiconductor substrate 110. A process of removing a portion of the first semiconductor substrate 110 may include, for example, a plasma etching process.

Referring to FIG. 6C, the first protection layer 121, the second protection layer 122, and a sacrificial layer 123 may be sequentially formed on the first surface 110a of the first wafer WF1. The formation of the first protection layer 121, the second protection layer 122, and the sacrificial layer 123 may be formed by a chemical vapor deposition method, an atomic layer deposition method, and a physical vapor deposition method. For example, the first protection layer 121 may be a silicon oxide layer, the second protection layer 122 may be a silicon nitride layer, and the sacrificial layer 123 may be a silicon oxide layer. The first protection layer 121, the second protection layer 122, and the sacrificial layer 123 may be formed along the first surface 110a of the first semiconductor substrate 110 and the first penetration via 170, which protrudes from the first surface 110a of the first semiconductor substrate 110. The second protection layer 122 and the sacrificial layer 123 may have a shape that is offset from the first protection layer 121.

Referring to FIG. 6D, a planarization process may be performed on the first penetration via 170, the first protection layer 121, and the second protection layer 122. The planarization process may be, for example, a chemical-mechanical polishing (CMP) process. The planarization process may be performed until the top surface of the second protection layer 122, which is not vertically overlapped with the first penetration via 170, is exposed to the outside. In an embodiment, the planarization process may be performed to remove the sacrificial layer 123 and to expose a top surface of the second protection layer 122, a top surface of a portion of the first protection layer 121 adjacent to the side surface of the first penetration via 170, and the top surface 170t of the first penetration via 170. The top surface 170t of the first penetration via 170, the portion of the top surface of the first protection layer 121, and the top surface of the second protection layer 122 may be substantially coplanar with each other. A portion of the first protection layer 121, a portion of the second protection layer 122, and a portion of the first penetration via 170 may be removed by the planarization process.

Referring to FIG. 6E, an upper portion of the first penetration via 170 may be removed. The removal of the first penetration via 170 may include, for example, a wet etching process. The wet etching process may be performed using an etchant including at least one of, for example, hydrogen peroxide (H₂O₂) and hydrofluoric acid (HF). The etching process may be performed until a level of the top surface 170t of the first penetration via 170 is lower than a level of the first surface 110a of the first semiconductor substrate 110. For example, the wet etching process may be performed for 10 to 30 seconds. The etching of the first penetration via 170 may be performed until the level of the top surface 170t of the first penetration via 170 is lowered than the level of the top surface 110a of the first semiconductor substrate 110. As a result of the etching process, a recess RE may be formed to expose an inner side surface of the first protection insulating structure 120 and an inner side surface of the penetration hole of the first semiconductor substrate 110.

Referring to FIG. 6F, a seed layer 141L may be formed on the exposed top surface and the exposed inner side surface of the first protection layer 121, the exposed top surface of the second protection layer 122, the exposed top surface of the first penetration via 170, and the exposed inner side surface of the first semiconductor substrate 110. The seed layer 141L may be conformally formed by, for example, an atomic layer deposition (ALD) method. The seed layer 141L may be formed to have a thickness ranging from 5 nm to 50 nm. The seed layer 141L may be formed to fill a portion of the recess RE. A photoresist layer PR may be formed on the seed layer 141L. The photoresist layer PR may be formed to have a thickness ranging from 5 μm to 20 μm. The photoresist layer PR may be formed using, for example, a spin coating method. The photoresist layer PR may fill a remaining portion of the recess RE, which is not filled with the seed layer 141L.

Referring to FIG. 6G, the photoresist layer PR may be patterned to form a photoresist pattern PM. The patterning of the photoresist layer PR may include forming an opening OP, which is overlapped with the first penetration via 170 in the second direction D2. The patterning of the photoresist layer PR may include an exposing process and a developing process. The photoresist pattern PM may be formed to expose a region where the first upper pad 140 of FIG. 1 will be formed. The photoresist layer PR may be transparent or semitransparent. A stepwise structure may be formed between the top surface 170t of the first penetration via 170 and the top surface 120t of the first protection insulating structure 120, and the profile of the stepwise structure may be transferred to the seed layer 141L covering the stepwise structure. The stepwise structure may serve as an alignment key to indicate the position of the upper pad.

According to a comparative example, if the stepwise structure is absent between the top surface 170t of the first penetration via 170 and the top surface 120t of the first protection insulating structure 120, an alignment key should be formed in a scribe lane of the first wafer WF1 to perform the exposing process. An additional photolithography process and an additional dry etching process may be required to form the alignment key in the scribe lane. By contrast, according to an embodiment of the inventive concept, by performing the wet etching process to form the stepwise structure between the first penetration via 170 and the first protection insulating structure 120, it may be possible to improve the efficiency of the fabrication process, compared to the comparative example. In addition, according to an embodiment of the inventive concept, the first penetration via 170 may be etched to have the top surface 170t, which is placed at a level lower than the top surface 110a of the first semiconductor substrate 110, not between the top surface 120t and the bottom surface of the first protection insulating structure 120. The top surface 170t of the first penetration via 170 may be spaced apart from the top surface 120t of the first protection insulating structure 120 by a level difference of 0.2 μm or larger, and thus, the level difference between the top surfaces 120t and 170t may serve as an alignment key that can be clearly or effectively recognized.

Referring to FIG. 6H, the first metal pattern 142 and the second metal pattern 143 may be sequentially formed through an electroplating process using the seed layer 141L as an electrode. In the case where the heigh difference between the top surface 170t of the first penetration via 170 and the top surface of the first protection insulating structure 120 is equal to or larger than 0.2 μm, a dimple-shaped region formed in a top portion of the first upper pad 140, due to the heigh difference. In the case where the dimple-shaped region is formed to have a depth less than or equal to 0.1 μm and greater than 0, a contact area between the first connection terminal 160 of the second semiconductor chip 100b and the top surface of the first upper pad 140 of the first semiconductor chip 100a may be increased. Since the contact area of the top surface of the first upper pad 140 of the first semiconductor chip 100a is increased, the contact resistance of the first upper pad 140 may be lowered and the contact strength of the first upper pad 140 may be increased. In the case where the level difference between the top surface 170t of the first penetration via 170 and the top surface 120t of the first protection insulating structure 120 is equal to or less than 0.4 μm, the dimple-shaped region may be formed to have a depth of 0.1 μm or larger, and in this case, it may be possible to prevent the contact area between the first connection terminal 160 of the second semiconductor chip 100b and the first upper pad 140 of the first semiconductor chip 100a from being reduced.

Referring to FIG. 6I, the photoresist pattern PM may be removed. The seed layer 141L may be patterned using the first and second metal patterns 142 and 143 as an etch mask. The seed layer 141L may be patterned to form the seed pattern 141. The first upper pad 140, which includes the seed pattern 141, the first metal pattern 142, and the second metal pattern 143, may be formed. The first semiconductor chip 100a may be formed by performing a sawing process on the first wafer WF1 along a sawing line SL on a scribe lane region.

Referring to FIG. 6J, a second wafer WF2 may be prepared. The second wafer WF2 may be a structure which has not yet been divided into a plurality of base chips 200 through a sawing process. The second wafer WF2 may include the second semiconductor substrate 210, the second protection insulating structure 220, the second penetration via 270, the second upper pad 240, the second lower pad 250, the second interconnection layer 230, and the second connection terminal 260. The second semiconductor substrate 210 may include the first surface 210a and the second surface 210b, which are opposite to each other, and a logic circuit (e.g., an interface circuit) may be disposed on the second surface 210b. The second wafer WF2 may be prepared through a method that is similar to the afore-described method of forming the first wafer WF1. The second penetration via 270 and the second upper pad 240 may be formed by a method that is the same as or similar to the method of forming the first penetration via 170 and the first upper pad 140 described with reference to FIGS. 6D to 6I. The first connection terminal 160 of the first semiconductor chip 100a may be aligned to the second upper pad 240, and the first semiconductor chip 100a may be mounted on the second surface 210b of the second wafer WF2. The second semiconductor chip 100b, the third semiconductor chip 100c, and the fourth semiconductor chip 100d may be sequentially mounted on the first semiconductor chip 100a. The mounting of the first to fourth semiconductor chips 100a to 100d may include a thermal compression process. In the thermal compression process, the adhesive layer 300 may be disposed between the second wafer WF2 and the first semiconductor chip 100a and between the first to fourth semiconductor chips 100a to 100d.

Referring to FIG. 6K, the mold layer 400 may be formed to cover the second wafer WF2 and the chip stack 100. A sawing process may be performed on the mold layer 400 and the second wafer WF2 along the sawing line SL. The base chip 200 may be formed as a result of the sawing process on the second wafer WF2, and thus, the semiconductor package 1000 may be formed.

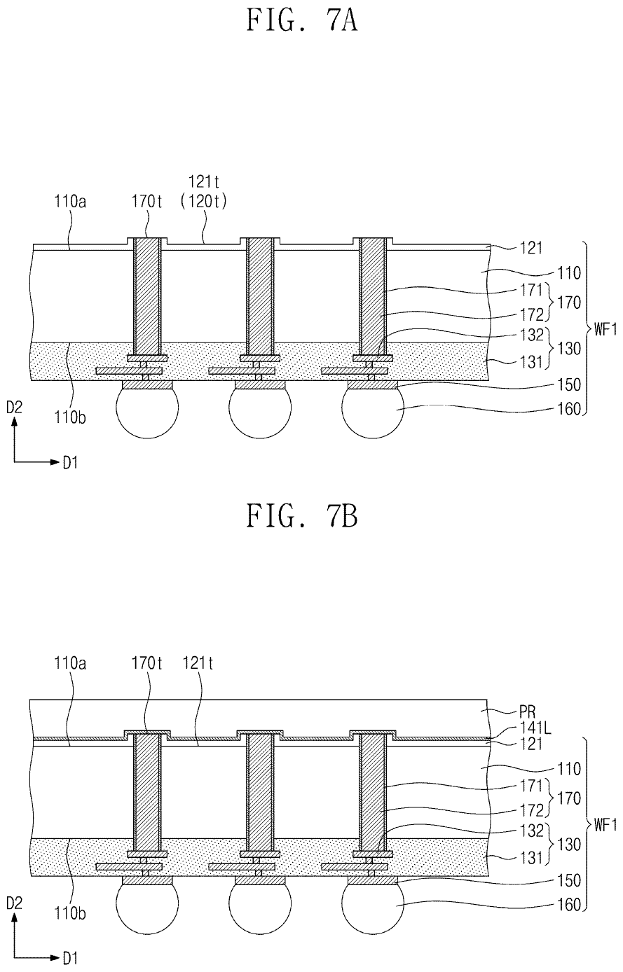

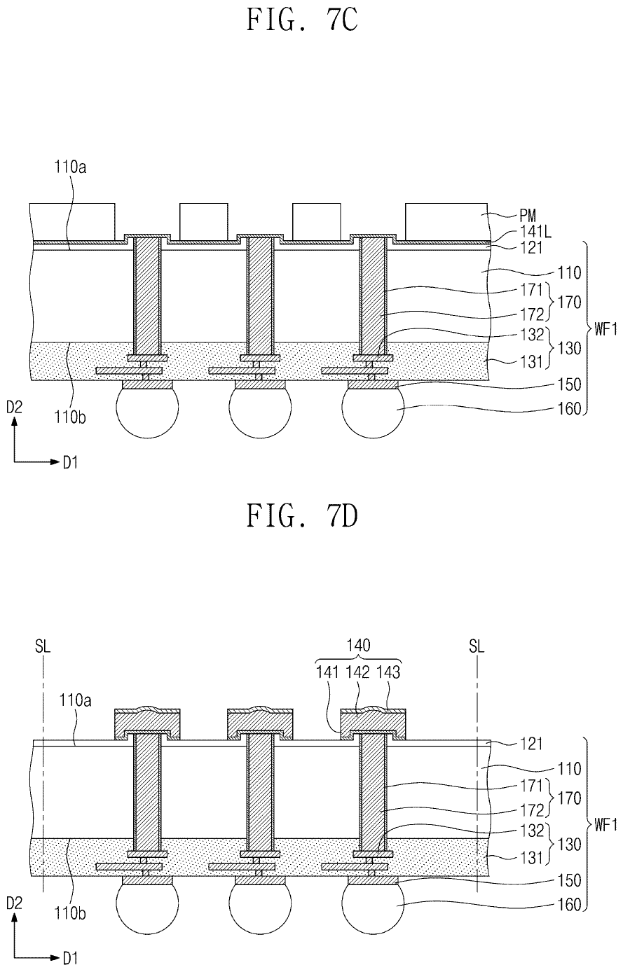

FIGS. 7A, 7B, 7C, and 7D are sectional views illustrating a process of fabricating a semiconductor package, according to an embodiment of the inventive concept. The element described with reference to FIGS. 3 and 4 may be identified by the same reference number without repeating an overlapping description thereof.

Referring to FIGS. 6D and 7A, the second protection layer 122 may be selectively removed. The second protection layer 122 may have an etch selectivity with respect to the first protection layer 121. The removal of the second protection layer 122 may include a wet etching process. For example, the second protection layer 122 may be removed using phosphoric acid (H₃PO₄). In an embodiment, the second protection layer 122 may be removed to expose the top surface of the first protection layer 121. Except for a portion of the first protection layer 121 extending along the side surface of the first penetration via 170 in the second direction D2, a top surface 121t of the first protection layer 121 may be lower than the top surface 170t of the first penetration via 170.

Referring to FIG. 7B, the seed layer 141L may be formed on the top surface of the first protection layer 121 and the top surface of the first penetration via 170. Next, the photoresist layer PR may be formed on the seed layer 141L.

Referring to FIG. 7C, the photoresist layer PR may be patterned to form the photoresist pattern PM. The photoresist pattern PM may be formed to expose a region where the first upper pad 140 of FIGS. 3 and 4 will be formed. A stepwise structure may be formed by the top surface 170t of the first penetration via 170 and the top surface 121t of the first protection layer 121, and the profile of the stepwise structure may be transferred to the seed layer 141L covering the stepwise structure. The stepwise structure may serve as an alignment key to indicate the position of the first upper pad 140. The top surface 170t of the first penetration via 170 may be spaced apart from the top surface 121t of the first protection layer 121 by a heigh difference of 0.2 μm or larger, and in this case, the heigh difference between the top surfaces 170t and 121t may serve as an alignment key that can be clearly or effectively recognized.

Referring to FIG. 7D, the first metal pattern 142 and the second metal pattern 143 may be sequentially formed through an electroplating process using the seed layer 141L as an electrode. In the case where the level difference between the top surface 170t of the first penetration via 170 and the top surface 121t of the first protection layer 121 is equal to or larger than 0.2 μm, a dome-shaped region may be formed in a top portion of the first upper pad 140, due to the level difference. In the case where the dome-shaped region is formed to have a height of 0.1 μm or less and greater than 0, a contact area of the top surface of the first upper pad 140 of the first semiconductor chip 100a, which is in contact with the first connection terminal 160 of the second semiconductor chip 100b, may be increased. In the case where the level difference between the top surface 170t of the first penetration via 170 and the top surface 120t of the first protection insulating structure 120 is equal to or less than 0.4 μm, the dome-shaped region may be formed to have a height of 0.1 μm or larger, and in this case, it may be possible to prevent the contact area between the first connection terminal 160 of the second semiconductor chip 100b and the first upper pad 140 of the first semiconductor chip 100a from being reduced.

The photoresist pattern PM may be removed, and the seed layer 141L may be patterned. In an embodiment, the seed layer 141L may be patterned to form the seed pattern 141. The first upper pad 140, which includes the seed pattern 141, the first metal pattern 142, and the second metal pattern 143, may be formed. The first semiconductor chip 100a may be formed by performing a sawing process on the first wafer WF1 along the sawing line SL.

Referring back to FIGS. 6J and 6K, the second wafer WF2 may be prepared. The second wafer WF2 may have a structure similar to the first wafer WF1, on which the sawing process of FIG. 7D has not yet been performed. The first to fourth semiconductor chips 100a to 100d may be mounted on the second surface 210b of the second wafer WF2. The adhesive layer 300 may be disposed between the second wafer WF2 and the first semiconductor chip 100a and between the first to fourth semiconductor chips 100a to 100d. The mold layer 400 may be formed to cover the second wafer WF2 and the chip stack 100. A sawing process may be performed on the mold layer 400 and the second wafer WF2 along the sawing line SL. The base chip 200 may be formed as a result of the sawing process on the second wafer WF2, and thus, a semiconductor package 1100 of FIG. 3 may be fabricated.

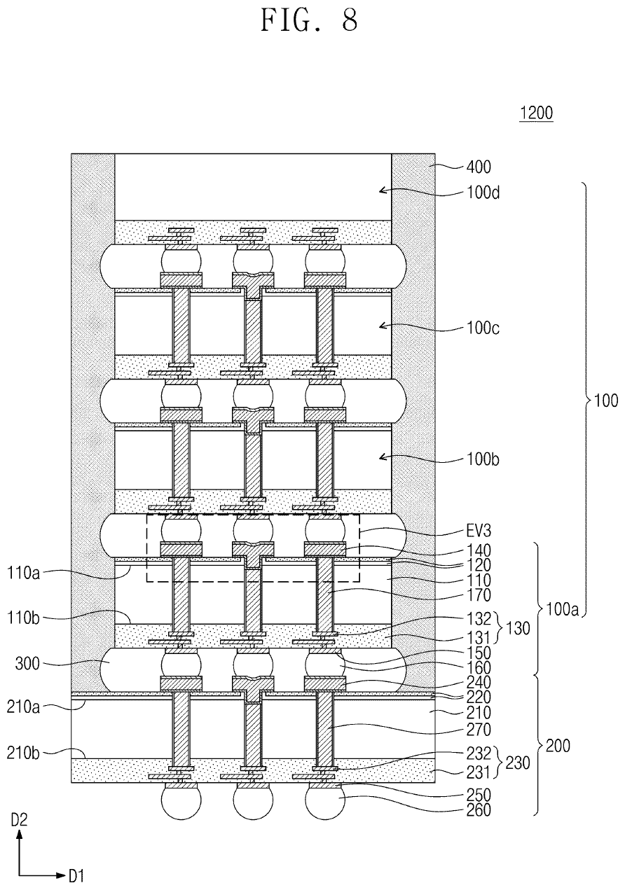

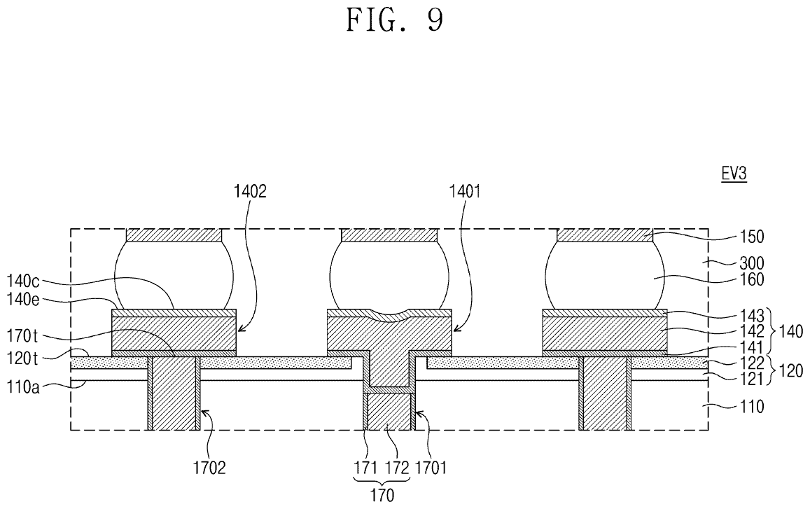

FIG. 8 is a sectional view illustrating a semiconductor package 1200 according to an embodiment of the inventive concept. FIG. 9 is an enlarged sectional view illustrating a portion EV3 of FIG. 8. Except for features to be described below, the semiconductor package 1200 according to the present embodiment may have substantially the same features as those described with reference to FIGS. 1 and 2, and thus, an overlapping description thereof may be omitted.

Referring to FIGS. 8 and 9, the first upper pads 140 may include a first sub-upper pad 1401 and a second sub-upper pad 1402, and the first penetration vias 170 may include a first sub-penetration via 1701 and a second sub-penetration via 1702.

The first sub-upper pad 1401 may correspond to the first upper pad 140 previously described with reference to FIGS. 1 and 2. The second sub-upper pad 1402 may include the pad portion 140P but may not include the via portion 140V. The second sub-upper pad 1402 may include the seed pattern 141, the first metal pattern 142, and the second metal pattern 143, similar to the first sub-upper pad 1401. The second sub-upper pad 1402 may have a top surface that is substantially flat. A level difference between the top surface 140c of the center region of the second sub-upper pad 1402 and the top surface 140e of the edge region of the second sub-upper pad 1402 may be smaller than a level difference between the top surface 140c of the center region of the first sub-upper pad 1401 and the top surface 140e of the edge region of the first sub-upper pad 1401. There may be no substantial difference in level between the top surface 140c of the center region of the second sub-upper pad 1402 and the top surface 140e of the edge region of the second sub-upper pad 1402. The first sub-penetration via 1701 may correspond to the first penetration via 170 previously described with reference to FIGS. 1 and 2. A level of the top surface 170t of the second sub-penetration via 1702 may be substantially equal to the level of the top surface 120t of the second protection layer 122. The level of the top surface 170t of the second sub-penetration via 1702 may be higher than the level of the top surface 170t of the first sub-penetration via 1701. The second upper pads 240 and the second penetration vias 270 of the base chip 200 may also have a structure similar to the first upper pads 140 and the first penetration vias 170.

According to an embodiment of the inventive concept, the semiconductor package 1200 shown in FIG. 8 may include a semiconductor chip including the penetration vias 1701 and 1702, which have top surfaces at different levels, and the upper pads 1401 and 1402, top surfaces of which differ in flatness.

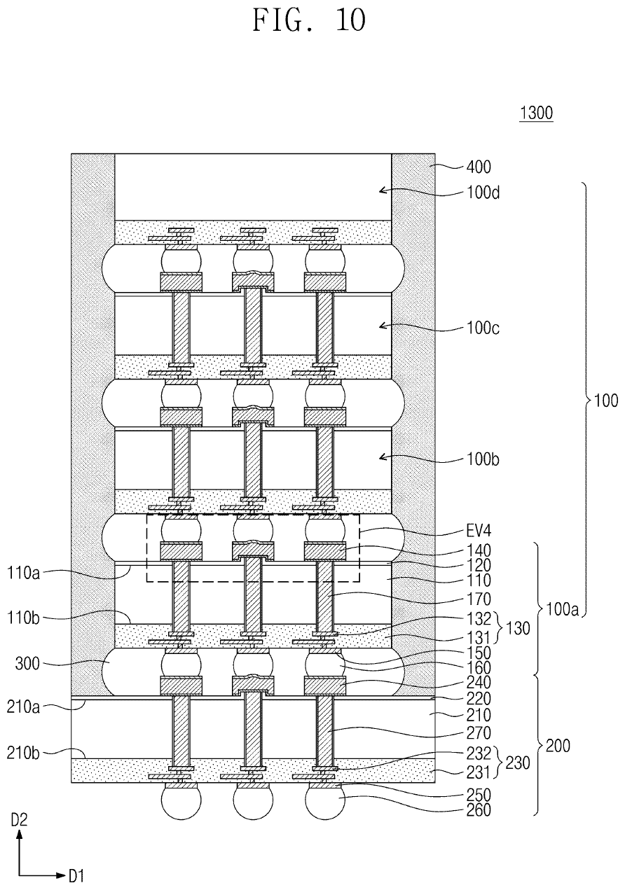

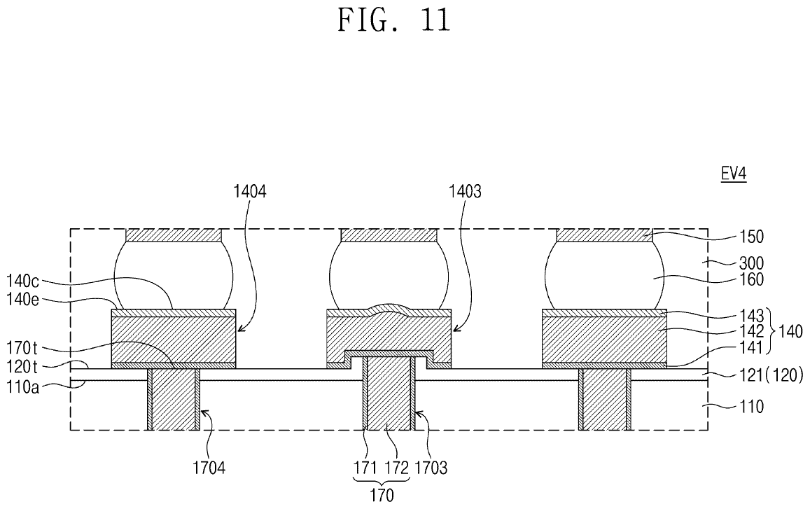

FIG. 10 is a sectional view illustrating a semiconductor package 1300 according to an embodiment of the inventive concept. FIG. 11 is an enlarged sectional view illustrating a portion EV4 of FIG. 10. Except for features to be described below, the semiconductor package 1300 according to the present embodiment may have substantially the same features as those described with reference to FIGS. 3 and 4, and thus, an overlapping description thereof may be omitted.

Referring to FIGS. 10 and 11, the first upper pads 140 may include a third sub-upper pad 1403 and a fourth sub-upper pad 1404, and the first penetration vias 170 may include a third sub-penetration via 1703 and a fourth sub-penetration via 1704.

The third sub-upper pad 1403 may correspond to the first upper pad 140 previously described with reference to FIGS. 3 and 4. The fourth sub-upper pad 1404 may have a substantially flat top surface. A level difference between the top surface 140c of the center region of the fourth sub-upper pad 1404 and the top surface 140e of the edge region of the fourth sub-upper pad 1404 may be smaller than a level difference between the top surface 140c of the center region of the third sub-upper pad 1403 and the top surface 140e of the edge region of the third sub-upper pad 1403.

The third sub-penetration via 1703 may correspond to the first penetration via 170 previously described with reference to FIGS. 3 and 4. A level of the top surface 170t of the fourth sub-penetration via 1704 may be substantially equal to a level of the top surface 120t of the first protection layer 121. A level of the top surface 170t of the fourth sub-penetration via 1704 may be lower than a level of the top surface 170t of the third sub-penetration via 1703. The second upper pads 240 and the second penetration vias 270 of the base chip 200 may also have a structure similar to the first upper pads 140 and the first penetration vias 170.

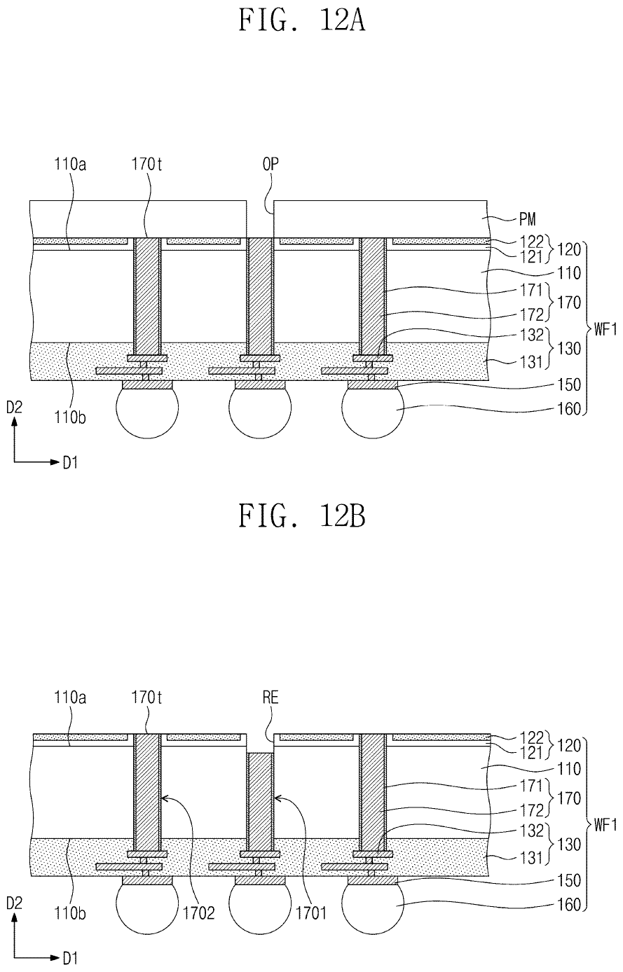

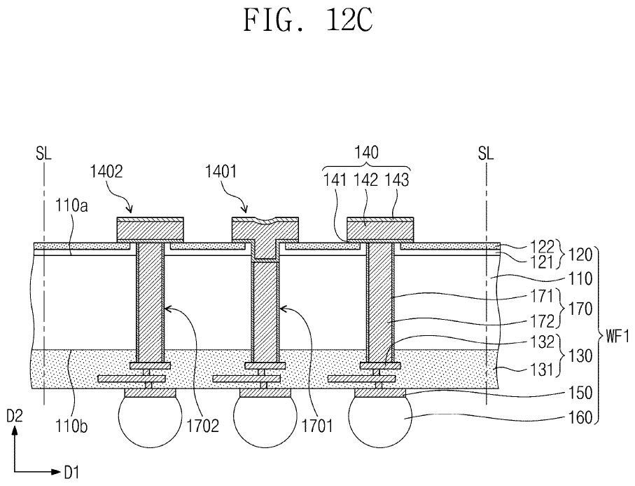

FIGS. 12A, 12B, and 12C are sectional views illustrating a process of fabricating a semiconductor package, according to an embodiment of the inventive concept.

Referring to FIG. 12A, the photoresist pattern PM may be formed on the top surface 170t of the first penetration via 170, the portion of the top surface of the first protection layer 121, and the top surface of the second protection layer 122 of FIG. 6D, which are coplanar with each other. The formation of the photoresist pattern PM may include forming a photoresist layer on the top surface 170t of the first penetration via 170, the top surface of the first protection layer 121, and the top surface of the second protection layer 122 and forming the opening OP, which is overlapped with at least one of the first penetration vias 170 in the second direction D2, in the photoresist layer. The remaining ones of the first penetration vias 170 may be covered with the photoresist pattern PM, and the top surfaces 170t thereof may not be exposed to the outside.

Referring to FIG. 12B, an upper portion of the first penetration via 170 exposed by the photoresist pattern PM may be partially removed. For example, an etching process (e.g., a wet etching process) may be performed to form the recess RE exposing the inner side surface of the first protection insulating structure 120 and the inner side surface of the penetration hole of the first semiconductor substrate 110. Next, the photoresist pattern PM may be removed. As a result of the etching process, the first sub-penetration via 1701 and the second sub-penetration via 1702 may be formed to have top surfaces at different levels.

Referring to FIG. 12C, the first and second sub-upper pads 1401 and 1402 may be formed on the first sub-penetration via 1701 and the second sub-penetration via 1702, respectively, using the method previously described with reference to FIGS. 6F, 6G, 6H, and 6I. The first semiconductor chip 100a may be formed by performing a sawing process on the first wafer WF1 along a sawing line SL on a scribe lane region. Next, the semiconductor package 1100 of FIG. 3 may be formed using the same method as FIGS. 6J and 6K.

According to an embodiment of the inventive concept, a stepwise structure, which is formed by a top surface of the first sub-penetration via 1701 and the top surface 120t of the first protection insulating structure 120, may serve as an alignment key to indicate the position of the upper pad. That is, it may be possible to easily determine the positions where the first and second sub-upper pads 1401 and 1402 are formed, based on the first sub-penetration via 1701.

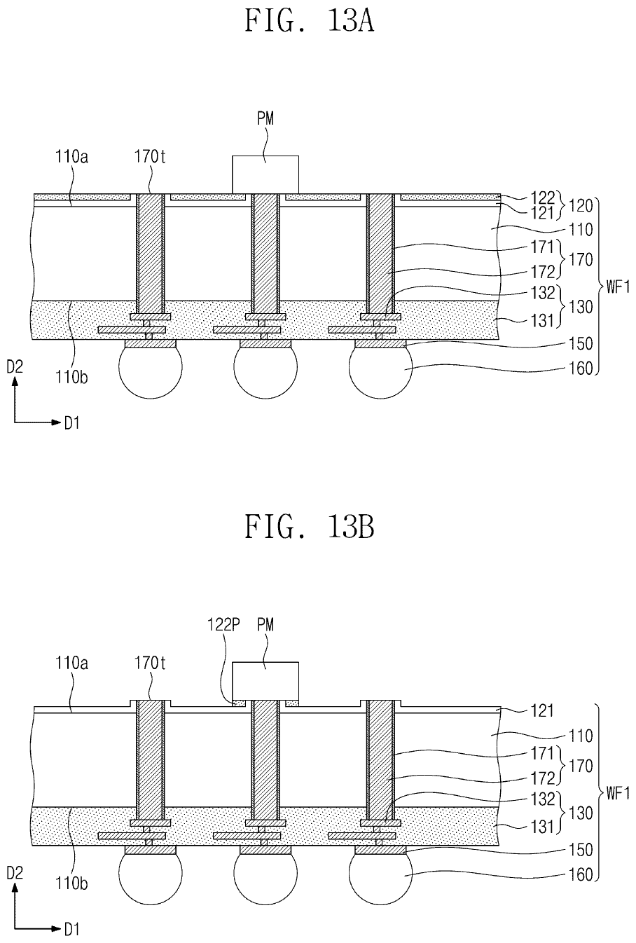

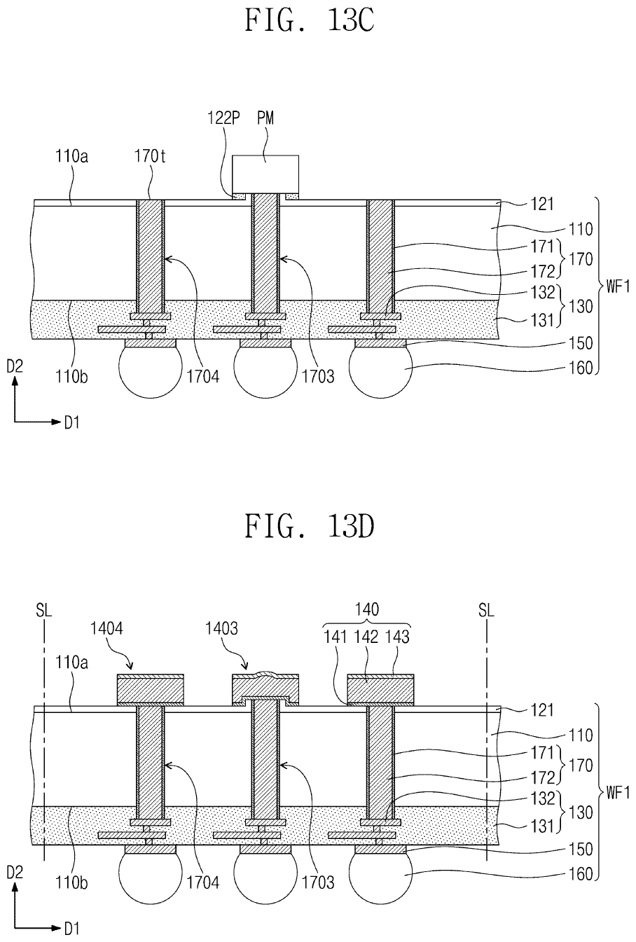

FIGS. 13A, 13B, 13C, and 13D are sectional views illustrating a process of fabricating a semiconductor package according to an embodiment of the inventive concept.

Referring to FIG. 13A, the photoresist pattern PM may be formed on a portion of the second protection layer 122 and a portion of the first penetration vias 170 of FIG. 6D. The photoresist pattern PM may be overlapped with a portion of the second protection layer 122 and at least one of the first penetration vias 170 in the second direction D2. The remaining ones of the first penetration vias 170 may have the top surfaces 170t exposed outside the photoresist pattern PM.

Referring to FIG. 13B, the second protection layer 122, which is not covered with the photoresist pattern PM, may be selectively removed. A portion of the second protection layer 122, which is overlapped with the photoresist pattern PM in the second direction D2, may be patterned to form a protection pattern 122P.

Referring to FIG. 13C, upper portions of the first penetration vias 170, which are not covered with the photoresist pattern PM, may be partially removed. A portion of the first protection layer 121, which is placed on the side surfaces of the upper portions of the first penetration vias 170, may be removed when the upper portions of the first penetration vias 170 are removed, or through an additional process. As a result, the third sub-penetration via 1703 and the fourth sub-penetration via 1704 may be formed to have top surfaces at different levels. The top surface 170t of the fourth sub-penetration via 1704 may be formed at substantially the same level as the top surface of the first protection layer 121.

Referring to FIG. 13D, the photoresist pattern PM and the protection pattern 122P of FIG. 13C may be removed. The third sub-upper pad 1403 and the fourth sub-upper pad 1404 may be formed on the third sub-penetration via 1703 and the fourth sub-penetration via 1704 using the same method as described with reference to FIGS. 7B, 7C, and 7D. The first semiconductor chip 100a of FIG. 10 may be formed by performing a sawing process on the first wafer WF1 along the sawing line SL on a scribe lane region. The method described with reference to FIGS. 6J and 6K may be used to form the semiconductor package 1300 of FIG. 10.

According to an embodiment of the inventive concept, a level of a top surface of a penetration via of a semiconductor chip may be different from a level of a top surface of a protection insulating structure. The level difference may be used as an alignment key, when an upper pad is formed on the penetration via. Thus, it may be possible to omit an additional process of forming the alignment key and to efficiently fabricate a semiconductor package.

According to an embodiment of the inventive concept, the upper pad on the penetration via may have a center region and an edge region whose top surfaces are placed at different levels. In this case, it may be possible to increase a contact area and a contact strength between the upper pad and a connection terminal, to reduce a contact resistance therebetween, and thereby to improve the reliability of the semiconductor package.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a first semiconductor chip; and
a second semiconductor chip disposed on the first semiconductor chip in a stacking direction,
wherein the first semiconductor chip comprises:
a first semiconductor substrate;
a first penetration via penetrating the first semiconductor substrate;
a protection insulating structure disposed on a top surface of the first semiconductor substrate; and
a first upper pad disposed on the first penetration via,
wherein the first upper pad comprises a center region, which overlaps the first penetration via in the stacking direction, and an edge region enclosing the center region,
the second semiconductor chip comprises a connection terminal in contact with the first upper pad,
a top surface of the first penetration via is located at a first level,
a top surface of the protection insulating structure is located at a second level,
a top surface of the center region of the first upper pad is located at a third level,
a top surface of the edge region of the first upper pad is located at a fourth level,
the first and second levels are different from each other, and
the third and fourth levels are different from each other.

2. The semiconductor package of claim 1, wherein a level of a bottom surface of the center region of the first upper pad is different from a level of a bottom surface of the edge region of the first upper pad.

3. The semiconductor package of claim 1, wherein a thickness of the center region of the first upper pad is different from a thickness of the edge region of the first upper pad.

4. The semiconductor package of claim 1, wherein the first level is lower than a level of the top surface of the first semiconductor substrate.

5. The semiconductor package of claim 1, wherein the first level is lower than the second level, and
the third level is lower than the fourth level.

6. The semiconductor package of claim 1, wherein a difference between the first and second levels is larger than a difference between the third and fourth levels.

7. The semiconductor package of claim 1, wherein a difference between the first and second levels ranges from 0.2 μm to 0.4 μm, and
a difference between the third and fourth levels is less than or equal to 0.1 μm and greater than 0.

8. The semiconductor package of claim 1, wherein the protection insulating structure comprises a silicon oxide layer and a silicon nitride layer disposed on the silicon oxide layer,
the semiconductor package further comprises an adhesive layer disposed between the first semiconductor chip and the second semiconductor chip, and
the adhesive layer is in contact with the silicon nitride layer and is spaced apart from the silicon oxide layer.

9. The semiconductor package of claim 1, wherein the protection insulating structure comprises a silicon oxide layer,
the semiconductor package further comprises an adhesive layer disposed between the first semiconductor chip and the second semiconductor chip, and
the adhesive layer is in contact with the silicon oxide layer.

10. The semiconductor package of claim 1, wherein the first semiconductor chip further comprises:
a second penetration via penetrating the first semiconductor substrate; and
a second upper pad disposed on the second penetration via,
wherein a top surface of the second penetration via is located at a fifth level, and the fifth level is different from the first level.

11. The semiconductor package of claim 1, wherein the first upper pad has a “T” shape, when viewed in a sectional view.

12. The semiconductor package of claim 1, wherein the first upper pad has an arch shape.

13. A semiconductor package, comprising:
a first semiconductor chip; and
a second semiconductor chip disposed on the first semiconductor chip in a stacking direction,
wherein the first semiconductor chip comprises:
a semiconductor substrate;
a penetration via penetrating the semiconductor substrate;
a protection insulating structure disposed on the semiconductor substrate; and
an upper pad disposed on the penetration via,
wherein a top surface of the penetration via is located at a level different from a top surface of the protection insulating structure,
wherein the second semiconductor chip comprises:
a lower pad disposed on the upper pad; and
a connection terminal between the upper pad and the lower pad,
wherein the upper pad comprises a center region overlapping the penetration via in the stacking direction, and
the center region has a top surface with an uneven structure.

14. The semiconductor package of claim 13, wherein a contact area between a top surface of the upper pad and the connection terminal is larger than a contact area between a bottom surface of the lower pad and the connection terminal.

15. The semiconductor package of claim 13, wherein the top surface of the center region has a dimple-shaped region.

16. The semiconductor package of claim 13, wherein the top surface of the center region has a dome shape.

17. The semiconductor package of claim 13, wherein a difference between a level of the top surface of the penetration via and a level of the top surface of the protection insulating structure ranges from 0.2 μm to 0.4 μm.

18. The semiconductor package of claim 13, wherein the upper pad comprises a via portion penetrating the protection insulating structure, and
a thickness of the via portion is larger than a thickness of the protection insulating structure.

19. The semiconductor package of claim 13, wherein the uneven structure has a height that is less than or equal to 0.1 μm and greater than 0.

20. A semiconductor package, comprising:
a package substrate;
an interposer disposed on the package substrate;
a sub-semiconductor package disposed on the interposer; and
a first semiconductor chip horizontally spaced apart from the sub-semiconductor package,
wherein the sub-semiconductor package comprises a second semiconductor chip and a third semiconductor chip stacked on the second semiconductor chip in a vertical direction,
wherein each of the second and third semiconductor chips comprises:
a semiconductor substrate including a first surface and a second surface facing each other;
a protection insulating structure disposed on the first surface of the semiconductor substrate;
an interconnection layer disposed on the second surface of the semiconductor substrate;
an upper pad disposed on the protection insulating structure;
a penetration via connected to the interconnection layer and the upper pad, and penetrating the semiconductor substrate;
a lower pad disposed on the interconnection layer; and
a connection terminal disposed on the lower pad,
wherein the connection terminal is interposed between the upper pad of the second semiconductor chip and the lower pad of the third semiconductor chip,
a top surface of the penetration via of the second semiconductor chip is located at a first level,
the first surface of the semiconductor substrate of the second semiconductor chip is located at a second level,
the first level is lower than the second level, and
a bottom surface of the lower pad of the third semiconductor chip is flatter than a top surface of the upper pad of the second semiconductor chip.
